(19) United States
(12) Patent Application Publication
(10) Pub. No.: US 2006/0091433 A1
(43) Pub. Date: May 4, 2006

(54) Semiconductor integrated circuit device and manufacturing method thereof

(76) Inventor: Kazumi Nishinohara, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/260,252

(22) Filed: Oct. 28, 2005

(30) Foreign Application Priority Data
Oct. 29, 2004 (JP) 2004-316686

(51) Int. Cl. H01L 29/76

(52) U.S. Cl. 257/288

(57) ABSTRACT

A semiconductor integrated circuit device includes a projected semiconductor layer formed at a part of the upper surface of a semiconductor substrate; a gate insulation film formed on a first side surface of the semiconductor layer; a gate electrode formed on the gate insulation film; a first insulation film formed on a second side surface of the semiconductor layer; and a source region and a drain region formed within the semiconductor layer to sandwich the gate electrode, wherein the first insulation film has a larger thickness than that of the gate insulation film.

### CROSS-REFERENCE TO RELATED APPLICATION

This application is based upon and claims the benefit of priority from the prior Japanese Patent Applications No. 2004-316686, filed on Oct. 29, 2004, the entire contents of which are incorporated herein by reference.

### BACKGROUND OF THE INVENTION

1. Field of the Invention

The present invention relates to a semiconductor integrated circuit device and a method of manufacturing the semiconductor integrated circuit device.

2. Background Art

Conventionally, along with high integration of a semiconductor integrated circuit device, miniaturization of a metal-oxide semiconductor field-effect transistor (MOSFET) within a semiconductor integrated circuit is proceeding. In order to breakthrough the limit of miniaturization of the semiconductor integrated circuit device, provision of the MOSFET in a three-dimensional structure is considered (for example, see Patent document 1: Japanese Patent Application Laid-Open No. 2002-110963).

Patent document 1 proposes a double-gate vertical MOSFET. A monocrystalline silicon layer of a silicon-on-insulator (SOI) substrate is cut into fine strips to form protrusions (Fin-portions). A gate insulation film and a gate electrode are crossed three-dimensionally on the fins, and the upper surface and both side surfaces of the protrusions are formed as channels. In other words, channel carrier layers are formed on both side surfaces and the upper surface of the protrusions, thereby operating a transistor.

Since this double-gate vertical MOSFET has channel carrier layers of at least two surfaces, a high current driving force can be obtained. When the bottom surface area of the protrusions is reduced and also when the protrusions are formed high, smaller space is required for the MOSFET than the space for a planar MOSFET. Therefore, the double-gate vertical MOSFET is promising as an element to be used for a future large-scale integration (LSI).

According to the conventional double-gate vertical MOSFET, a short-channel effect cannot be disregarded when miniaturization is to be proceeded to increase the driving capacity. In order to suppress the short-channel effect, it is necessary to reduce the thickness of the protrusions of the monocrystalline silicon layer in substantially the same channel lengths, thereby increasing the influence of an electric field from a gate electrode. For example, when a gate length is 30 nm, the thickness of the protrusions of the monocrystalline silicon layer must be within a range from 7 nm to 10 nm.

However, when the thickness of the protrusions of the monocrystalline silicon layer is reduced, the protrusions of the monocrystalline silicon layer fall down during a manufacturing process. In other words, the protrusions of the monocrystalline silicon layer do not have sufficient mechanical strength, and therefore fall down, which aggravates a production yield of non-defective products. When the thickness of the protrusions of the monocrystalline silicon layer is reduced to about 10 nm or below, the driving force does not increase, but decreases. This is because when the thickness of the protrusions of the monocrystalline silicon layer is reduced to about 10 nm, two inversion layers that become the factor of the high driving force of the double-gate vertical MOSFET are not formed. It is generally known that the inversion layer has a thickness of about 3 nm to 30 nm. When the thickness of the protrusions of the monocrystalline silicon layer is reduced to about 10 nm, the thickness of the protrusions of the monocrystalline silicon layer becomes smaller than two times the thickness of the inversion layer. Consequently, a current of two times cannot be applied, and the driving force of the vertical MOSFET decreases.

### SUMMARY OF THE INVENTION

A semiconductor integrated circuit device according to an embodiment of the present invention includes a projected semiconductor layer formed at a part of the upper surface of a semiconductor substrate; a gate insulation film formed on a first side surface of the semiconductor layer; a gate electrode formed on the gate insulation film; a first insulation film formed on a second side surface of the semiconductor layer; and a source region and a drain region formed within the semiconductor layer to sandwich the gate electrode, wherein the first insulation film has a larger thickness than that of the gate insulation film.

A semiconductor integrated circuit device according to an embodiment of the present invention includes a first insulation film formed in a projected manner at a part of the upper surface of a semiconductor substrate; first and second semiconductor layers formed in a projected manner on the upper surface of the semiconductor substrate such that first side surfaces of the first and the second semiconductor layers are in close contact with opposite side surfaces of the first insulation film, respectively; a gate insulation film formed on second side surfaces opposite to the first side surfaces of the first and the second semiconductor layers, respectively; a gate electrode formed on the gate insulation film; and a source region and a drain region formed on the second side surfaces within the first and the second semiconductor layers, respectively to sandwich the gate electrode.

A method of manufacturing a semiconductor integrated circuit device according to an embodiment of the present invention includes forming a trench on a semiconductor substrate; forming a first insulation film with one end of the first insulation film embedded within the trench, and the other end projected from the surface of the semiconductor substrate; forming a side wall made of a second insulation film at a side of the projected first insulation film; etching partially the semiconductor substrate at both sides of the projected first insulation film using the first insulation film and the second insulation film as a mask, thereby forming a projected first semiconductor layer and a projected second semiconductor layer beneath the second insulation film; forming a gate insulation film on side surfaces of the first and the second semiconductor layers; forming a gate electrode on the surface of the gate insulation film on the side surface of the first semiconductor layer to the surface of the gate insulation film on the side surface of the second semiconductor layer, by striding on the first insulation film and the second insulation film; and injecting impurity into the side surfaces of the first and the second semiconductor layers, thereby forming a source region and a drain region to sandwich the gate electrode.

A method of manufacturing a semiconductor integrated circuit device according to an embodiment of the present invention includes forming a trench on a semiconductor substrate; forming a first insulation film with one end of the first insulation film embedded within the trench, and the other end projected from the surface of the semiconductor substrate; forming a side wall made of a second insulation film at a side of the projected first insulation film; etching partially the semiconductor substrate at both sides of the projected first insulation film using the first insulation film and the second insulation film as a mask, thereby forming a projected first semiconductor layer and a projected second semiconductor layer beneath the second insulation film; forming a gate insulation film on side surfaces of the first and the second semiconductor layers; forming a gate electrode on the surface of the gate insulation film on the side surface of the first semiconductor layer to the surface of the gate insulation film on the side surface of the second semiconductor layer, by striding on the first insulation film and the second insulation film; forming a side wall on a side part of the semiconductor substrate that is covered with the second insulation film, the gate insulation film, and the gate electrode; and injecting impurity into a part of the semiconductor substrate that is not covered with the second insulation film, the gate insulation film, the gate electrode, and the side wall, thereby forming a source region and a drain region.

### BRIEF DESCRIPTION OF THE DRAWINGS

FIG. 1 is a perspective diagram showing a configuration of the vertical MOSFET according to the first embodiment;

FIG. 2 is a cross-sectional diagram of the vertical MOSFET cut along a line A1-A2 on the vertical plane shown in FIG. 1;

FIG. 3 is a cross-sectional diagram of the vertical MOSFET cut along a line B1-B2 on the horizontal plane shown in FIG. 1;

FIG. 4 is a perspective diagram showing a configuration of the vertical MOSFET according to the second embodiment of the present invention;

FIG. 5 is a cross-sectional diagram of the vertical MOSFET cut along a line C1-C2 on the vertical plane shown in FIG. 4;

FIG. 6a is a cross-sectional diagram of the vertical MOSFET cut along a line A1-A2 in FIG. 4 showing a process of manufacturing the vertical MOSFET;

FIG. 6b is a cross-sectional diagram showing a process of manufacturing the vertical MOSFET following FIG. 6a;

FIG. 6c is a cross-sectional diagram showing a process of manufacturing the vertical MOSFET following FIG. 6b;

FIG. 6d is a cross-sectional diagram showing a process of manufacturing the vertical MOSFET following FIG. 6c;

FIG. 6e is a cross-sectional diagram showing a process of manufacturing the vertical MOSFET following FIG. 6d;

FIG. 6f is a cross-sectional diagram showing a process of manufacturing the vertical MOSFET following FIG. 6e;

FIG. 6g is a cross-sectional diagram showing a process of manufacturing the vertical MOSFET following FIG. 6f;

FIG. 6h is a cross-sectional diagram showing a process of manufacturing the vertical MOSFET following FIG. 6g;

FIG. 6i is a cross-sectional diagram showing a process of manufacturing the vertical MOSFET following FIG. 6h;

FIG. 7 is a perspective diagram showing a configuration of the vertical MOSFET according to the third embodiment of the present invention;

FIG. 8 is a cross-sectional diagram of the vertical MOSFET cut along a line D1-D2 on the vertical plane shown in FIG. 7;

FIG. 9a is a cross-sectional diagram of the vertical MOSFET cut along a line D1-D2 in FIG. 7 showing a process of manufacturing the vertical MOSFET;

FIG. 9b is a cross-sectional diagram showing a process of manufacturing the vertical MOSFET following FIG. 6a;

FIG. 9c is a cross-sectional diagram showing a process of manufacturing the vertical MOSFET following FIG. 9b;

FIG. 9d is a cross-sectional diagram showing a process of manufacturing the vertical MOSFET following FIG. 9c;

FIG. 9e is a cross-sectional diagram showing a process of manufacturing the vertical MOSFET following FIG. 9d;

FIG. 9f is a cross-sectional diagram showing a process of manufacturing the vertical MOSFET following FIG. 9f;

FIG. 9g is a cross-sectional diagram showing a process of manufacturing the vertical MOSFET following FIG. 9g;

FIG. 10 is a perspective diagram showing a configuration of the vertical MOSFET according to the fourth embodiment;

FIG. 11 is a cross-sectional diagram of the vertical MOSFET cut along a line E1-E2 on the horizontal plane shown in FIG. 10;

FIG. 12a is a cross-sectional diagram of the vertical MOSFET cut along a line E1-E2 in FIG. 10 showing a process of manufacturing the vertical MOSFET;

FIG. 12b is a cross-sectional diagram showing a process of manufacturing the vertical MOSFET following FIG. 12a;

FIG. 12c is a cross-sectional diagram showing a process of manufacturing the vertical MOSFET following FIG. 12b; and

FIG. 12d is a cross-sectional diagram showing a process of manufacturing the vertical MOSFET following FIG. 12c.

### DETAILED DESCRIPTION OF THE INVENTION

Embodiments of application of the present invention to a semiconductor integrated circuit device having a vertical MOSFET will be explained in detail below with reference to the accompanying drawings.

### First Embodiment

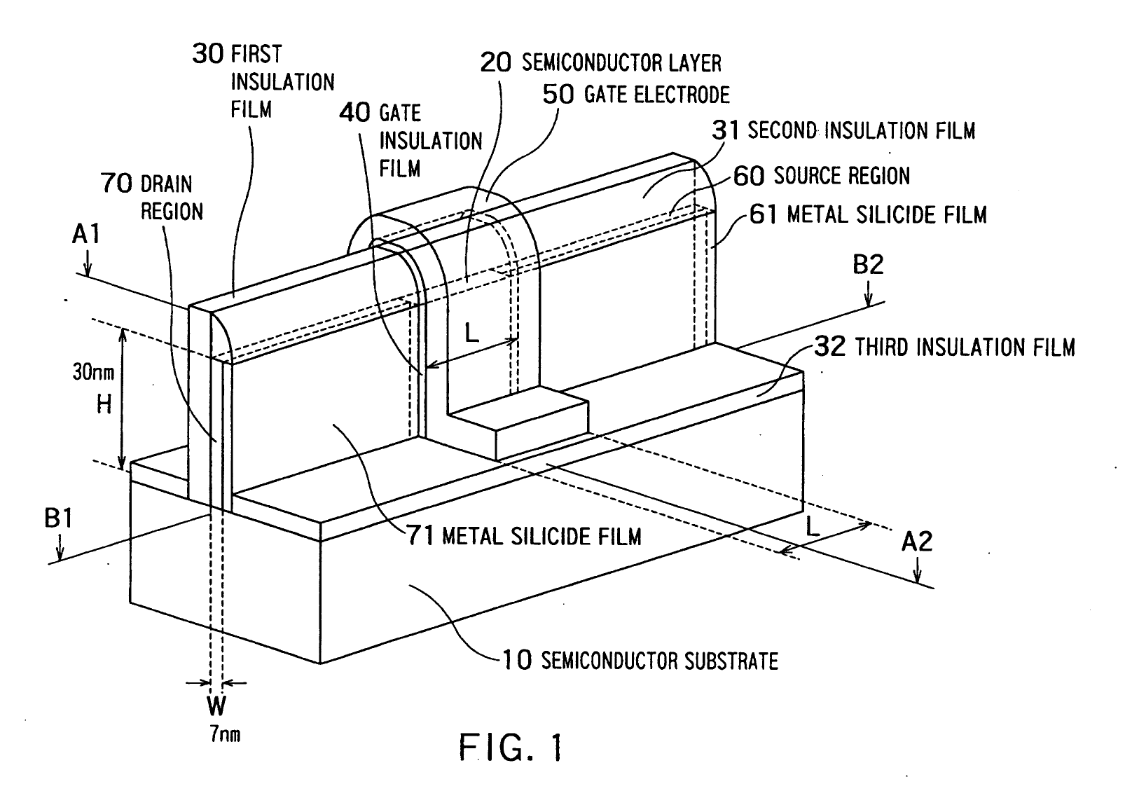

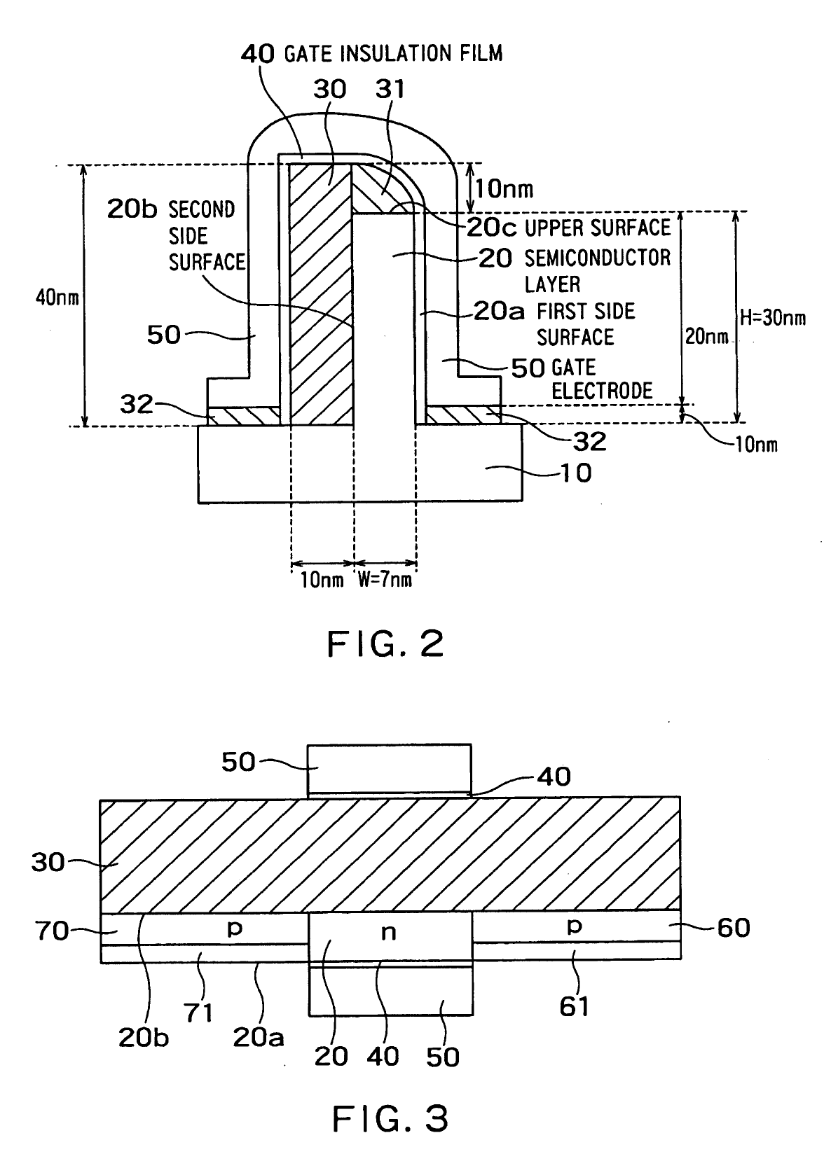

A vertical MOSFET according to a first embodiment of the present invention is explained with reference to FIG. 1 to FIG. 5. FIG. 1 is a perspective diagram showing a configuration of the vertical MOSFET according to the first embodiment. FIG. 2 is a cross-sectional diagram of the vertical MOSFET cut along a line A1-A2 on the vertical plane, as seen in the direction of the arrow, shown in FIG. 1. In the present embodiment, a configuration of a P-type MOSFET is explained below. An N-type MOSFET can be also obtained when impurity and polarity of voltage are reversed.

As shown in FIG. 1 and FIG. 2, a projected semiconductor layer 20 having a rectangular cross section is formed on a part of an upper surface of a semiconductor substrate 10. This semiconductor layer 20 has a first side surface (the right side surface of the semiconductor layer 20 in FIG. 2) 20a and a second side surface (the left side surface of the semiconductor layer 20 in FIG. 2) 20b that are opposite to each other, and an upper surface 20c. In this case, the semiconductor layer 20 is formed integrally with the semiconductor substrate 10 by processing the upper surface of the semiconductor substrate 10, to have a thickness (W) of about 7 nm, and a height (H) of about 30 nm from the upper surface of the semiconductor substrate 10.

A first insulation film 30 made of an oxide film (SiO2) is formed on the second side surface 20b of the semiconductor layer 20 on the semiconductor substrate 10. A second insulation film 31 made of a nitride film (SiN) is formed on the upper surface 20c of the semiconductor layer 20. In order to mechanically hold the semiconductor layer 20 and in order to prevent formation of a channel on the second side surface 20b of the semiconductor layer 20, the first insulation film 30 has a film thickness of about 10 nm, for example, which is larger than that of a gate insulation film 40, described later, and has a width which is about the same as that of the semiconductor layer 20.

Further, the first insulation film 30 has a height of about 40 nm, for example, from the upper surface of the semiconductor substrate 10, which is larger than the height of the semiconductor substrate 10. The difference in height between the upper surface of the first insulation film 30 and the upper surface 20c of the semiconductor layer 20 is about 10 nm.

The second insulation film 31 fills the height difference between the semiconductor layer 20 and the first insulation film 30. A gate electrode 50, described later, is formed to have a film thickness of 10 nm, for example, which is larger than the thickness of the gate insulation film 40, described later, to prevent formation of a channel on the upper surface of the semiconductor layer 20. The second insulation film 31 is not limited to the SiN film, and can be made of the same material as that of the first insulation film 30, such as a SiO2 film.

The gate insulation film 40 made of SiO2 is formed to cover the first side surface 20a of the semiconductor layer 20 on a predetermined part of the semiconductor layer 20. In other words, the gate insulation film 40 is formed on the side surface of the first insulation film 30, from the first side surface 20a of the semiconductor layer 20, striding on the supper surfaces of the second insulation film 31 and the first insulation film 30. It is sufficient that the gate insulation film 40 is formed on at least the first side surface 20a of the semiconductor layer 20.

The gate insulation film 40 has a film thickness of about 1 nm, and has a width (L) of about 20 nm. The width (L) of the gate insulation film 40 becomes a channel length when a gate bias is applied.

A third insulation film 32 is formed in contact with the semiconductor layer 20 on the semiconductor substrate 10. The third insulation film 32 has a thickness of 10 nm, for example, and is made of SiN, SiO2, or the like.

The gate electrode 50 is formed on the gate insulation film 40 and the third insulation film 32. While the gate electrode 50 is formed on the whole surface of the gate insulation film 40, it is sufficient that the gate electrode 50 is formed to cover at least the upper surface of the gate insulation film 40 on the first side surface 20a of the gate insulation film 40.

A metal or a metal compound having a work function near the center of a silicon band gap such as titanium nitride is used for the gate electrode 50. Alternatively, polysilicon that is used for a gate electrode of a general transistor can be also used for the gate electrode 50.

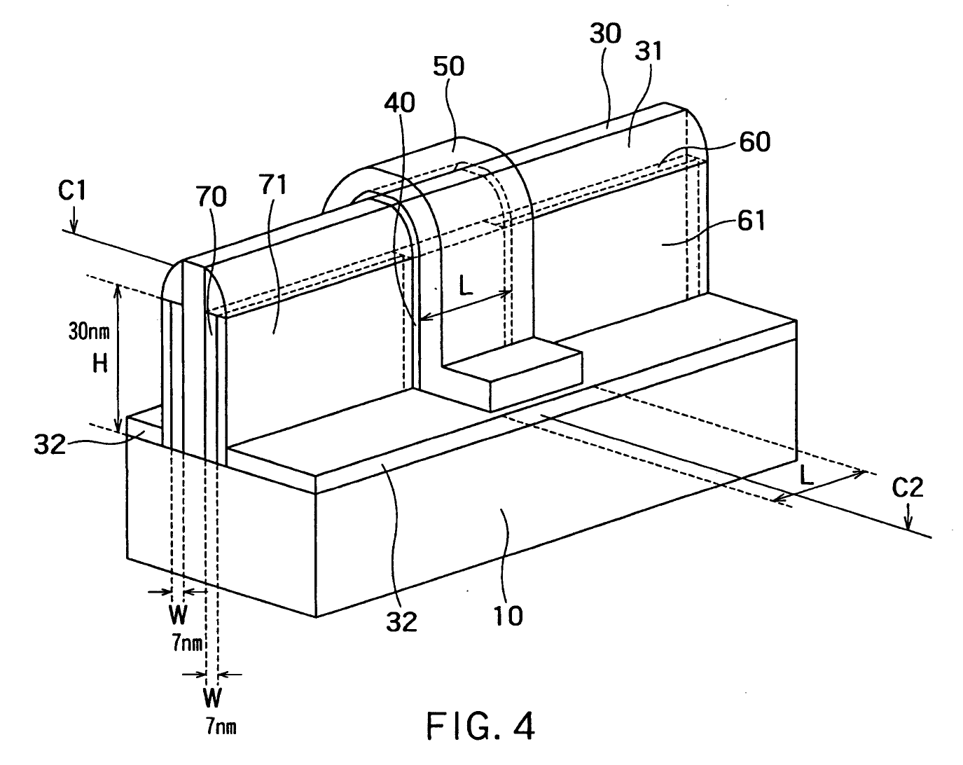

FIG. 3 is a cross-sectional diagram of the vertical MOSFET cut along a line B1-B2 on the horizontal plane, as seen in the direction of the arrow, shown in FIG. 1. In FIG. 3, a source region 60 and a drain region 70 having a conductivity type (P-type) opposite to the conductivity type of the semiconductor layer 20 are formed with a distance from each other, on the right and left sides of the semiconductor layer 20, respectively.

The source region 60 and the drain region 70 have boron (B) as impurity, and are formed in self-alignment with the gate electrode 50 within both side surfaces of the first side surface 20a at both sides of the gate electrode 50.

Impurity is not injected to a part covered by the gate insulation film 40 and the gate electrode 50, that is, a part where a channel is formed when gate bias is applied, out of the semiconductor layer 20. Concentration of the impurity at the part where a channel is formed is the same as the concentration of the impurity of the semiconductor layer 20, for example, about 2E17 cm-3 or below.

A metal silicide film 61 and a metal silicide film 71 are formed on the surfaces of the source region 60 and the drain region 70, respectively. With this arrangement, a satisfactory ohmic contact can be obtained between the metal silicide film 61 and the source region 60 and between the metal suicide film 71 and the drain region 70, respectively.

While metal silicide is provided in the source region 60 and the drain region 70 to form the metal silicide film 61 and the metal silicide film 71, respectively, the source region 60 can be used as a source electrode and the drain region 70 can be used as a drain electrode without providing metal silicide, respectively.

The first insulation film 30, the second insulation film 31, and the third insulation film 32 are not necessarily single layers, respectively, and can be multi-layer insulation films consisting of plural kinds of layers, respectively.

The first insulation film 30, the second insulation film 31, the third insulation film 32, and the gate insulation film 40 can be formed using the same materials. However, the first insulation film 30, the second insulation film 31, and the third insulation film 32 are required to have sufficiently larger film thicknesses than that of the gate insulation film 40, respectively. A low-k film having a low dielectric constant can be used for the first insulation film 30, the second insulation film 31, and the third insulation film 32, respectively. A high-k film having a high dielectric constant can be used for the gate insulation film 40.

In the above embodiment, the first insulation film 30 having a sufficiently larger film thickness than that of the gate insulation film 40 is provided between the second side surface 20b of the semiconductor layer 20 and the gate electrode 50, thereby constituting a single-gate vertical MOSFET having a channel on only the side surface 20a of the semiconductor layer 20. This is different from the double-gate vertical MOSFET having channels on both side surfaces of the protrusion (the semiconductor layer) according to the conventional technique. According to the single-gate vertical MOSFET, even when the thickness (W) of the semiconductor layer 20 is 10 nm or smaller, an inversion layer is formed on only the side surface 20a of the semiconductor layer 20. Therefore, driving force does not decrease even when the vertical MOSFET having a thickness (W) of 10 nm or smaller is formed.

Further, since the second insulation film 31 having a sufficiently larger film thickness than that of the gate insulation film 40 is provided on the upper surface 20c of the semiconductor layer 20, a channel is not formed on the upper surface 20c of the semiconductor layer 20. Consequently, it is possible to suppress the occurrence of the problem that an electric field is concentrated around the corner at the right upper side of the semiconductor layer 20 shown in FIG. 2 where channels are superimposed, and the carrier concentration increases, thereby increasing a leak current at the right upper corner of the semiconductor layer 20.

By providing the first insulation film 30 having a sufficiently larger film thickness than that of the gate insulation film 40 between the first side surface 20a of the semiconductor layer 20 and the gate electrode 50, a parasitic capacitance of the first insulation film can be reduced. With this arrangement, a parasitic capacitance of the vertical MOSFET can be reduced. Consequently, the switching speed of the MOSFET can be improved.

Further, since the first insulation film 30 having a large width mechanically holds the semiconductor layer 20, the height (H) of the semiconductor layer 20 can be increased. The area of a part where a channel is formed can be substantially increased without increasing the area of the semiconductor substrate (chip) of the semiconductor integrated circuit. Since one side surface of the semiconductor layer 20 is supported with the adjacent first insulation film 30, the strength of the semiconductor layer 20 can be increased. Consequently, a semiconductor integrated circuit device having a channel part of a high aspect ratio that does not fall down easily can be formed.

### Second Embodiment

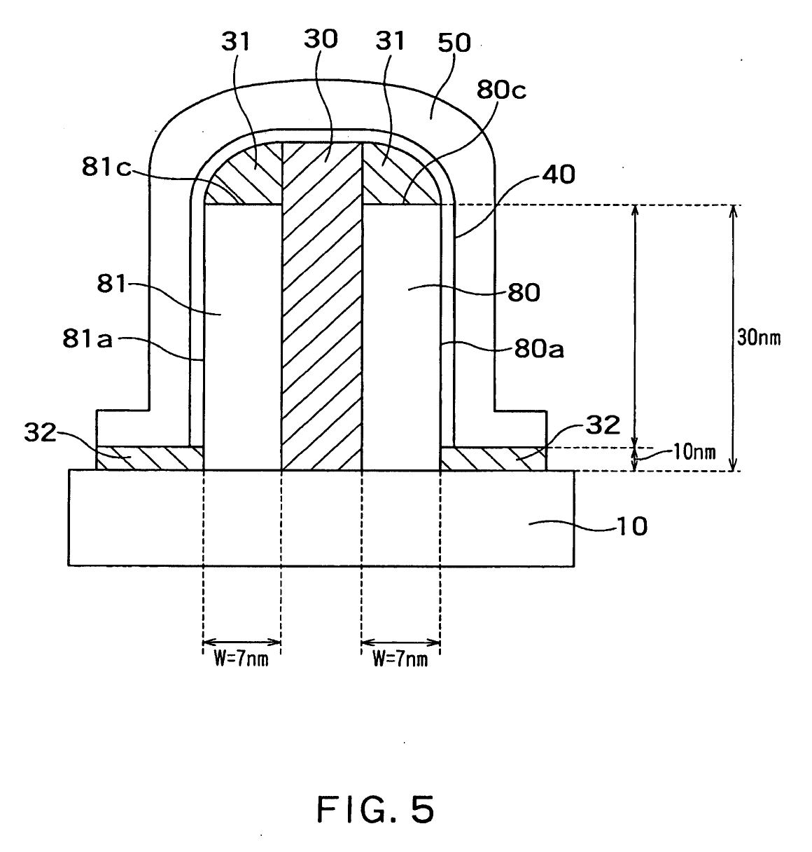

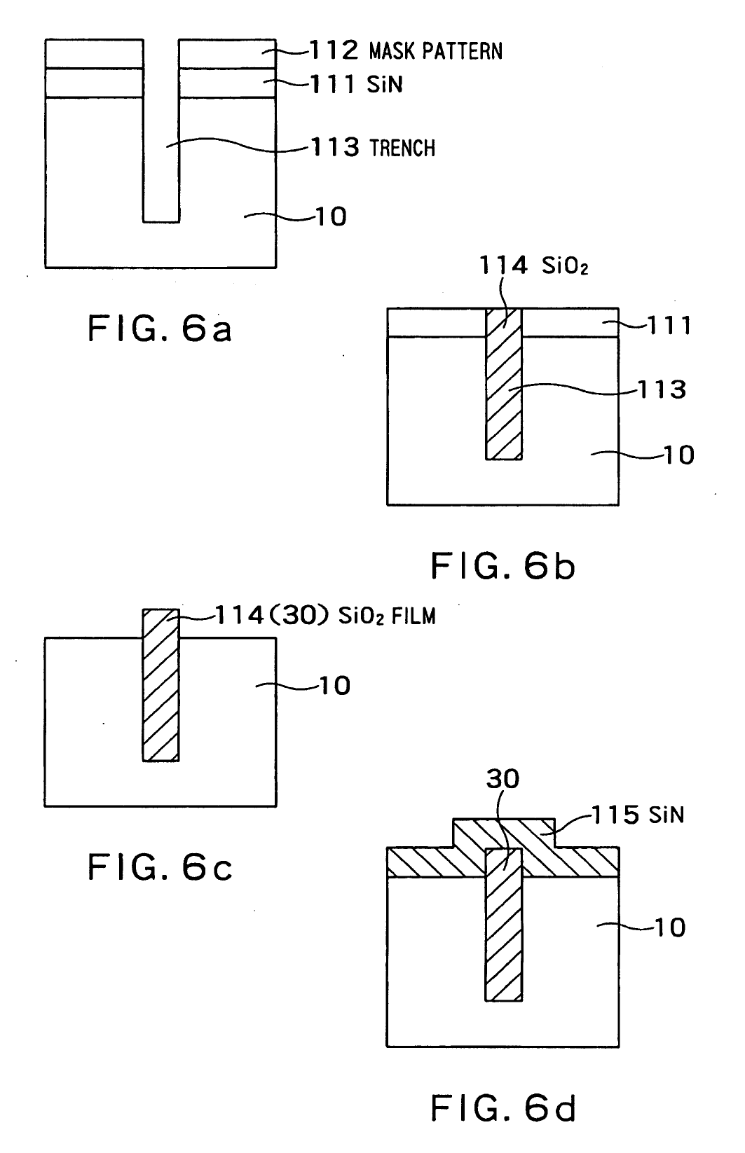

A vertical MOSFET according to a second embodiment of the present invention is explained with reference to FIG. 4 and FIG. 5. FIG. 4 is a perspective diagram showing a configuration of the vertical MOSFET according to the second embodiment. FIG. 5 is a cross-sectional diagram of the vertical MOSFET cut along a line C1-C2 on the vertical plane, as seen in the direction of the arrow, shown in FIG. 4. In the present embodiment, a single-gate vertical MOSFET is provided at both sides of the first insulation film 30. In FIG. 4 and FIG. 5, constituent parts similar to those according to the first embodiment are designated with like reference numerals, and explanation of these parts is omitted.

As shown in FIG. 4 and FIG. 5, the projected first insulation film 30 made of SiO2 having a rectangular cross section is formed on a part of the upper surface of the semiconductor substrate 10 so as to project therefrom. A projected semiconductor layer 80 having a rectangular cross section is formed on one of two side surfaces of the first insulation film 30. A projected semiconductor layer 81 having a rectangular cross section is formed on the other side surface of the first insulation film 30.

The semiconductor layers 80 and 81 are similar to the semiconductor layer 20 explained in the first embodiment. The semiconductor layers 80 and 81 have smaller heights than that of the first insulation film 30, and are projected from the upper surface of the semiconductor substrate 10, in close contact with the side surfaces of the first insulation film 30. The semiconductor layers 80 and 81 have a height (H) of about 30 nm from the semiconductor substrate 10, and a thickness (W) of about 7 nm, similarly to the semiconductor layer 20 explained in the first embodiment.

The second insulation film 31 made of SiN is formed on upper surfaces 80c and 81c of the semiconductor layers 80 and 81, respectively in close contact with the side surfaces of the first insulation film 30. The first insulation film 30 and the second insulation film 31 are not necessarily made of different materials, and can be made of the same material.

The gate insulation film 40 is formed at a predetermined part of the semiconductor layer 80 to cover a side surface 80a of the semiconductor layer 80, and the gate insulation film 40 is formed at a predetermined part of the semiconductor layer 81 to cover a side surface 81a of the semiconductor layer 81.

The third insulation film 32 is formed on the semiconductor substrate 10 to be in contact with the semiconductor layers 80 and 81.

The gate electrode 50 is formed to cover the third insulation film 32 and the gate insulation film 40. It is sufficient that the gate electrode 50 is formed to cover at least the upper surface of the gate insulation film 40.

The source region 60 and the drain region 70 having a conductivity type (P-type) opposite to the conductivity type of the semiconductor layers 80 and 81 are formed with a distance from each other at both sides of the semiconductor layers 80 and 81 to sandwich the gate electrode 50.

The metal silicide film 61 and the metal silicide film 71 are formed on the surfaces of the source region 60 and the drain region 70, respectively. With this arrangement, a satisfactory ohmic contact can be obtained between the metal silicide film 61 and the source region 60 and between the metal suicide film 71 and the drain region 70, respectively. Consequently, a contact resistance can be reduced. The vertical MOSFET according to the present embodiment is formed in the above described manner.

The vertical MOSFET according to the present embodiment has the first insulation film 30 formed to be shared on the surfaces of the semiconductor layers where the gate insulation film is not formed. As a result, the area where the vertical MOSFET is formed like that explained in the first embodiment can be reduced, thereby reducing the area of the semiconductor integrated circuit device.

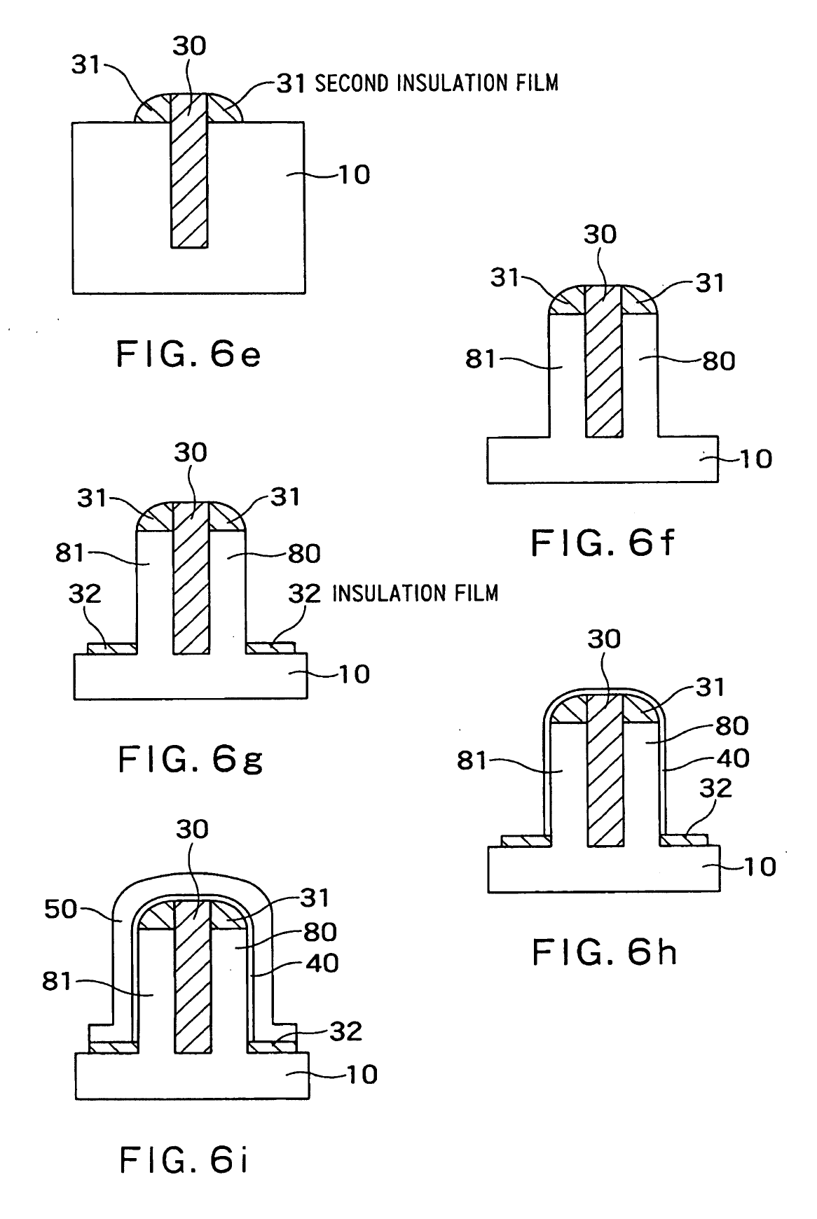

A method of manufacturing the vertical MOSFET having the above configuration is explained next with reference to FIG. 4 to FIGS. 6a to 6i. FIGS. 6a to 6i are cross-sectional diagrams showing the process of manufacturing the vertical MOSFET. FIGS. 6a to 6i are cross-sectional diagrams of the vertical MOSFET cut along a line C1-C2 on the vertical plane, as seen in the direction of the arrow, shown in FIG. 4.

As shown in FIG. 6a, a SiN film 111 is deposited by a CVD method on the whole upper surface of the semiconductor substrate 10 made of silicon (Si). A mask pattern 112 of resist is formed on the upper surface of the SiN film 111, according to the lithographic technique. This SiN film 111 has the same film thickness as that of the second insulation film 31 shown in FIG. 4. The SiN film 111 is used to form the projected first insulation film 30, described later.

A trench 113 is formed in the region of the semiconductor substrate 10 not covered with the resist mask pattern 112. In forming the trench 113, the SiN film 111 part not covered with the mask pattern 112 is removed by etching. Then, the semiconductor substrate 10 is etched by the anisotropic dry etching up to the middle of the semiconductor substrate 10, thereby forming the trench 113. In this etching, it is preferable to form a side wall of the trench 113 vertically. A known technique used to provide an STI can be used to form the trench 113.

Next, as shown in FIG. 6b, the mask pattern 112 is removed, and then, a SiO2 film 114 is deposited by the CVD method on the SiN film 111 and the semiconductor substrate 10 to fill the trench 113. The SiO2 film 114 other than the trench 113 is polished and removed by a CMP method until when the upper surface of the SiN film 111 is exposed, and therefore, the SiO2 film 114 is embedded into the trench 113.

Thereafter, as shown in FIG. 6c, the SiN film 111 is selectively removed with hot phosphoric acid or the like. As a result, the first insulation film 30 made of a SiO2 film having a rectangular cross section projected from the upper surface of the semiconductor substrate 10 is formed as shown in FIG. 4 and FIG. 5.

Next, as shown in FIG. 6d, SiN 115 is deposited by the CVD method on the whole surface of the semiconductor substrate 10 and the first insulation film 30.

Thereafter, as shown in FIG. 6e, the SiN film 115 is etched by anisotropic etching such as RIE, thereby forming the second insulation film 31 made of SiN on the side surfaces of the projected first insulation film 30. As a result, the second insulation film 31 as shown in FIG. 4 is formed on the side surfaces of the projected first insulation film 30.

Next, as shown in FIG. 6f, the region of the semiconductor substrate 10 at the outside of the projected first insulation film 30 and the second insulation film 31 is etched up to the middle of the semiconductor substrate 10 by anisotropic dry etching. In this case, the region of the semiconductor substrate 10 is etched up to the same position as that of the bottom surface of the first insulation film 30. Based on this etching, the semiconductor layers 80 and 81 that are projected from the upper surface of the semiconductor substrate 10 are formed in close contact with the first insulation film 30 at both sides of the projected first insulation film 30 as shown in FIG. 4. The depth of this etching determines the height of the semiconductor layers 80 and 81.

Thereafter, as shown in FIG. 6g, the third insulation film 32 is deposited by the CVD method on the exposed surface of the semiconductor substrate 10 and at the sides of the semiconductor layers 80 and 81. The deposited third insulation film 32 is flattened by the CMP and is etched back to remain the third insulation film 32 of about 10 nm as a depth on the bottom of the trench. The third insulation film 32 is made of SiN, SiO2, or the like.

Next, as shown in FIG. 6h, the gate oxide film 40 is formed on the semiconductor layers 80 and 81 by thermal oxidation or the like. Polysilicon is formed on the gate oxide film 40 by the CVD method, and SiN is deposited. The polysilicon is patterned according to the lithographic technique, thereby forming the gate electrode 50 made of polysilicon.

Thereafter, as shown in FIG. 4, the source region 60 and the drain region 70 are formed at both sides of the gate electrode 50, that is, on the semiconductor layers 80 and 81 at both sides of the channel forming region. The source region 60 and the drain region 70 are formed in self-alignment with the gate electrode 50 by injecting boron (B) by an ion injection method into both left and right side surfaces of the first side surface of the semiconductor layers 80 and 81 excluding the lower part of the gate electrode 50 using the gate electrode 50 and the SiN film as a mask. This SiN film is provided to prevent impurity from entering the polysilicon film as the gate electrode 50.

Thereafter, titanium (Ti) is formed by sputtering on each surface of the source region 60 and the drain region 70. The titanium is heat treated to form the metal silicide films 61 and 71 made of titan silicide in the source region 60 and the drain region 70. As a result, a satisfactory ohmic contact can be obtained between the source region 60 and the metal silicide film 61 and between the drain region 70 and the metal silicide film 71.

In the manner as described above, the single-gate vertical MOSFET can be formed on each side surface of the projected first insulation film 30 as shown in FIG. 4 and FIG. 5.

The projected first insulation film 30 and the semiconductor layers 80 and 81 shown in FIG. 6c can be also formed as follows. A mask is formed on the semiconductor substrate 10 by the lithographic technique. A SiO2 film is formed on the exposed upper surface part of the semiconductor substrate 10. The mask is removed, and the projected first insulation film 30 is formed. A semiconductor material is deposited by a selective epitaxial growth on the upper surface part of the semiconductor substrate 10 at both sides of the first insulation film 30, thereby forming the projected semiconductor layers 80 and 81.

In the above embodiment, two vertical MOSFETs according to the first embodiment are combined together. This configuration has an effect similar to that obtained according to the first embodiment.

Further, the first insulation film 30 is provided between the two semiconductor layers 80 and 81. The gate electrode 50 is formed to cover the first insulation film 30 and the semiconductor layers 80 and 81. Thus, the semiconductor layers 80 and 81 share the first insulation film 30 and the gate electrode 50. Therefore, a higher integration can be realized by the present embodiment than that obtained when two vertical MOSFETs of the first embodiment are simply combined together.

Further, according to the above manufacturing method, the first insulation film having high strength mechanically supports the semiconductor layer. Therefore, there is no risk that the semiconductor layer falls down. Consequently, a highly reliable vertical MOSFET can be manufactured. Further, a semiconductor layer of high aspect ratio can be easily formed, and driving force of the FET can be increased.

### Third Embodiment

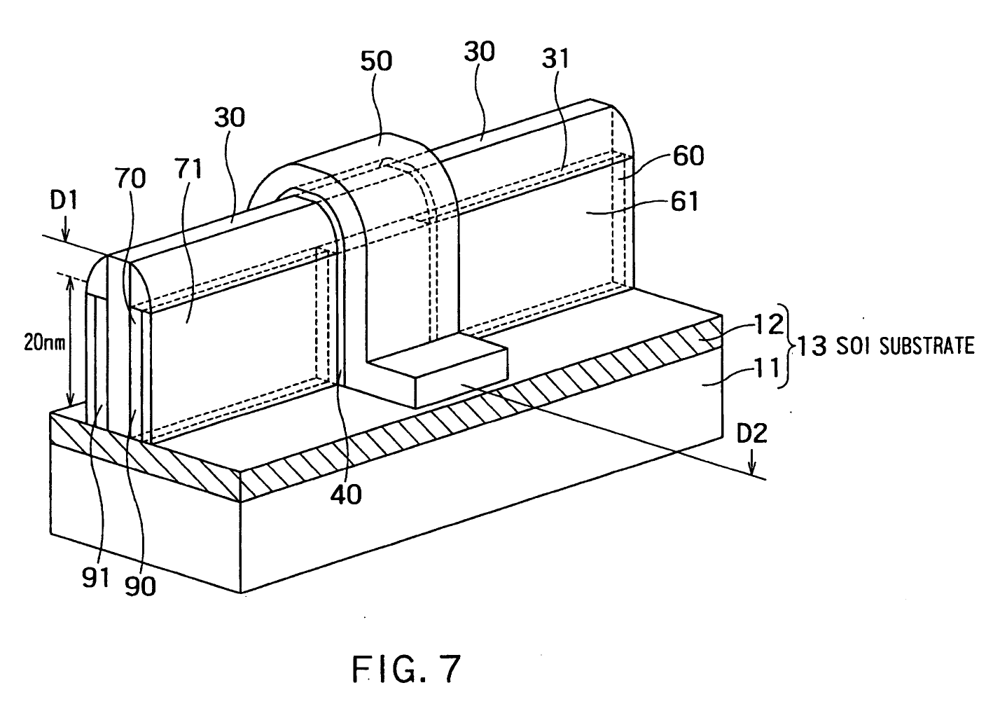

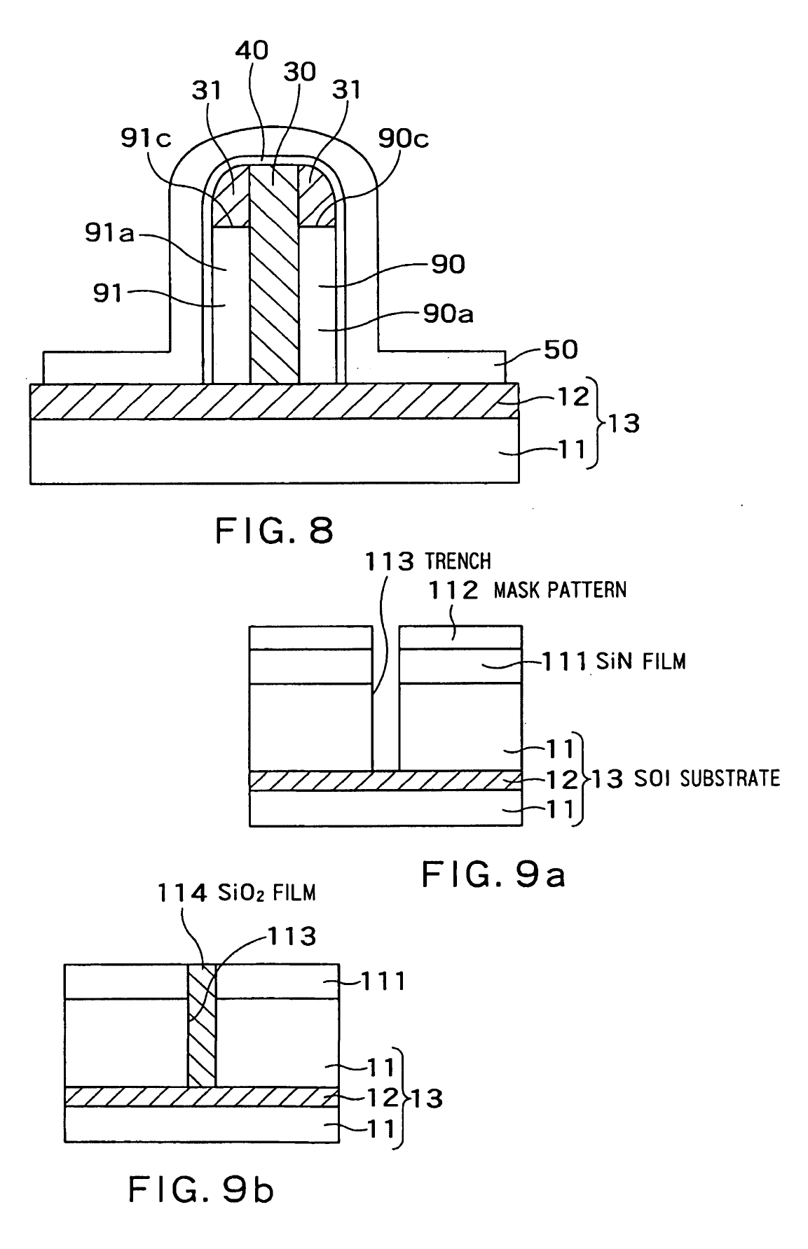

A vertical MOSFET according to a third embodiment of the present invention is explained with reference to FIG. 7 and FIG. 8. FIG. 7 is a perspective diagram showing a configuration of the vertical MOSFET according to the third embodiment. FIG. 8 is a cross-sectional diagram of the vertical MOSFET cut along a line D1-D2 on the vertical plane, as seen in the direction of the arrow, shown in FIG. 7. In FIG. 7 and FIG. 8, constituent parts similar to those according to the second embodiment are designated with like reference numerals, and explanation of these parts is omitted.

In the present embodiment, a semiconductor substrate having an SOI configuration (hereinafter, simply referred to as an SOI substrate) 13 is used in place of the semiconductor substrate 10. In other words, as shown in FIG. 7 and FIG. 8, the projected first insulation film 30 is formed on an insulation layer 12 of the SOI substrate 13. A projected semiconductor layer 90 having a rectangular cross section is formed on one of two side surfaces of the first insulation film 30. A projected semiconductor layer 91 having a rectangular cross section is formed on the other side surface of the first insulation film 30.

The semiconductor layers 90 and 91 are similar to the semiconductor layer 20 explained in the first embodiment and the semiconductor layers 80 and 81 explained in the second embodiment. The semiconductor layers 90 and 91 have smaller heights than that of the first insulation film 30, and are projected from the upper surface of a BOX film 12 of the SOI substrate 13, in close contact with the side surfaces of the first insulation film 30. The semiconductor layers 90 and 91 have a height (H) of about 20 nm from the front surface of the BOX film 12 of the SOI substrate 13, and a thickness (W) of about 7 nm.

The second insulation film 31 made of SiN is formed on upper surfaces 90c and 91c of the semiconductor layers 90 and 91, respectively in close contact with the side surfaces of the first insulation film 30. The first insulation film 30 and the second insulation film 31 are not necessarily made of different materials, and can be made of the same material.

The gate insulation film 40 is formed at a predetermined part of the semiconductor layer 90 to cover a first side surface 90a of the semiconductor layer 90, and the gate insulation film 40 is formed at a predetermined part of the semiconductor layer 91 to cover a first side surface 91a of the semiconductor layer 91.

The gate electrode 50 is formed to cover the first insulation film 30, the second insulation film 31, the gate electrode 40, and the semiconductor layers 90 and 91. It is sufficient that the gate electrode 50 is formed to cover at least the upper surface of the gate insulation film 40.

The source region 60 and the drain region 70 having a conductivity type (P-type) opposite to the conductivity type of the semiconductor layers 90 and 91 are formed with a distance from each other at both sides of the semiconductor layers 90 and 91 to sandwich the gate electrode 50.

The metal silicide film 61 and the metal silicide film 71 are formed on the surfaces of the source region 60 and the drain region 70, respectively. With this arrangement, a satisfactory ohmic contact can be obtained between the metal silicide film 61 and the source region 60 and between the metal silicide film 71 and the drain region 70, respectively. Consequently, a contact resistance can be reduced. The vertical MOSFET according to the present embodiment is formed in the manner as described above.

The vertical MOSFET according to the present embodiment has the first insulation film 30 formed to be shared on the surfaces of the semiconductor layers where the gate insulation film is not formed. As a result, the area where the vertical MOSFET is formed like that explained in the first embodiment can be reduced, thereby reducing the area of the semiconductor integrated circuit device.

Further, since the insulation layer 12 is present between the semiconductor region 11 of the SOI substrate 13 and the semiconductor layers 90, 91, when channels are formed in the semiconductor layers 90, 91 and a current flows through the channels, no current flows through the semiconductor region 11. Therefore, a leak current can be reduced.

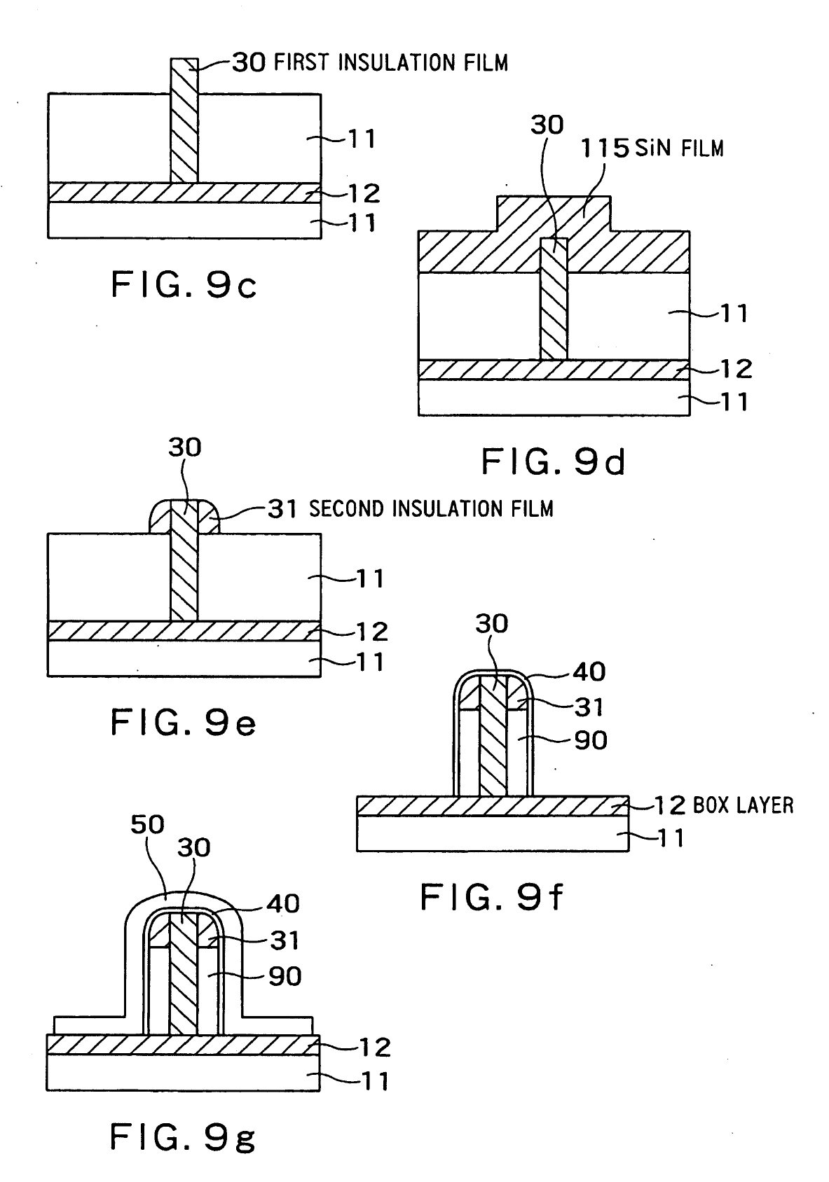

A method of manufacturing the vertical MOSFET having the above configuration is explained next with reference to FIGS. 9a to 9g. FIGS. 9a to 9g are cross-sectional diagrams showing the process of manufacturing the vertical MOSFET. FIGS. 9a to 9g are cross-sectional diagrams of the vertical MOSFET cut along a line D1-D2 on the vertical plane, as seen in the direction of the arrow, shown in FIG. 7.

As shown in FIG. 9a, the SiN film 111 is deposited by the CVD method on the whole upper surface of the semiconductor region 11 of the SOI substrate 13. The resist mask pattern 112 is formed on the upper surface of the SiN film 111, according to the lithographic technique.

The trench 113 is formed in the semiconductor region 11 not covered with the resist mask pattern 112. In forming the trench 113, the SiN film 111 part not covered with the mask pattern is removed by etching. Then, the semiconductor region 11 is etched by the anisotropic dry etching up to the insulation layer 12, thereby forming the trench 113. In this etching, it is preferable to form a side wall of the trench 113 vertically.

Next, as shown in FIG. 9b, the mask pattern 112 is removed, and the SiO2 film 114 is embedded into the trench 113. In other words, the SiO2 film 114 is deposited on the SiN film 111 and the semiconductor region 11 by the CVD method. In depositing the SiO2 film 114, this film is filled within the trench 113. The SiO2 film 114 other than the SiO2 film 114 in the trench 113 is polished and removed by the CMP method until when the upper surface of the SiN film 111 is exposed, and the SiO2 film 114 is embedded into the trench 113.

Thereafter, as shown in FIG. 9c, the SiN film 111 is selectively removed with hot phosphoric acid or the like. As a result, the first insulation film 30 made of a SiO2 film having a rectangular cross section projected from the upper surface of the insulation layer 12 of the SOI substrate 13 is formed as shown in FIG. 7 and FIG. 8.

Next, as shown in FIG. 9d, SiN 115 is deposited on the whole surface of the SOI substrate 13 and the first insulation film 30.

Thereafter, as shown in FIG. 9e, the SiN film 115 is etched by anisotropic etching such as RIE, thereby forming a side wall made of SiN on the side surfaces of the projected first insulation film 30. As a result, the second insulation film 31 as shown in FIG. 7 and FIG. 8 is formed on the side surfaces of the projected first insulation film 30.

Next, as shown in FIG. 9f, the semiconductor region 11 at the outside of the second insulation film 31 is etched by anisotropic dry etching. The semiconductor region 11 is etched until when the insulation layer 12 is exposed. Based on this etching, the semiconductor layers 90 and 91 that are projected from the upper surface of the BOX film of the SOI substrate 13 are formed in close contact with the first insulation film 30 at both sides of the projected first insulation film 30 as shown in FIG. 7 and FIG. 8.

Next, as shown in FIG. 9g, the gate oxide film 40 is formed on the semiconductor layers 90 and 91 by thermal oxidation or the like. Polysilicon is formed on the gate oxide film 40 by the CVD method, and SiN is deposited. The polysilicon is patterned according to the lithographic technique, thereby forming the gate electrode 50 made of polysilicon.

Thereafter, as shown in FIG. 7 and FIG. 8, the source region 60 and the drain region 70 are formed at both sides of the gate electrode 50, that is, on the semiconductor layers 90 and 91 at both sides of the channel forming region. The source region 60 and the drain region 70 are formed in self-alignment by injecting boron (B) by the ion injection method into both left and right side surfaces of the first side surface 20a of the semiconductor layers 90 and 91 excluding the lower part of the gate electrode 50 using the gate electrode 50 and the SiN film as a mask. This SiN film is provided to prevent impurity from entering the polysilicon film as the gate electrode 50.

Thereafter, titanium (Ti) is formed by sputtering on each surface of the source region 60 and the drain region 70. The titanium is heat treated to form the metal silicide films 61 and 71 made of titan suicide in the source region 60 and the drain region 70. As a result, a satisfactory ohmic contact can be obtained between the source region 60 and the metal silicide film 61 and between the drain region 70 and the metal silicide film 71.

In the manner as described above, the single-gate vertical MOSFET can be formed on each side surface of the projected first insulation film 30 provided on the insulation layer 12 of the SOI substrate 13 as shown in FIG. 7 and FIG. 8.

According to the above embodiment, since the insulation layer 12 is present between the semiconductor region 11 of the SOI substrate 13 and the semiconductor layers 90, 91, when channels are formed in the semiconductor layers 90, 91 and a current flows through the channels, no current flows through the semiconductor region 11. Therefore, a leak current can be reduced.

It is not necessary to embed an insulation film to isolate elements. As a result, the process of manufacturing the semiconductor integrated circuit device can be simplified.

Further, according to the above manufacturing method, since the SOI substrate 13 is used, the insulation layer 12 works as an etching stopper at the time of forming a trench and at the time of etching to determine a channel width, therefore, working is facilitated.

### Fourth Embodiment

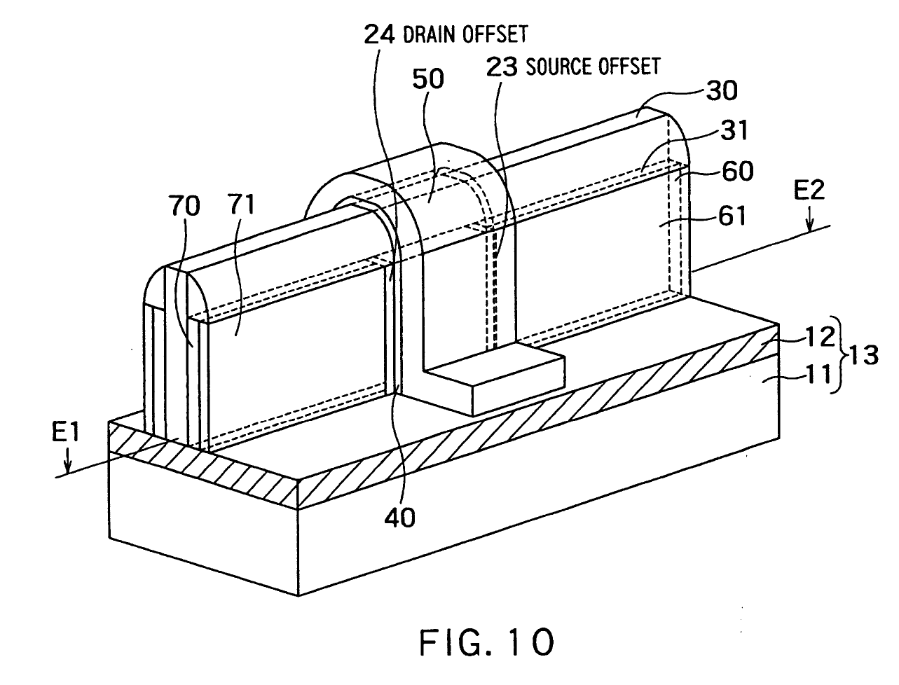

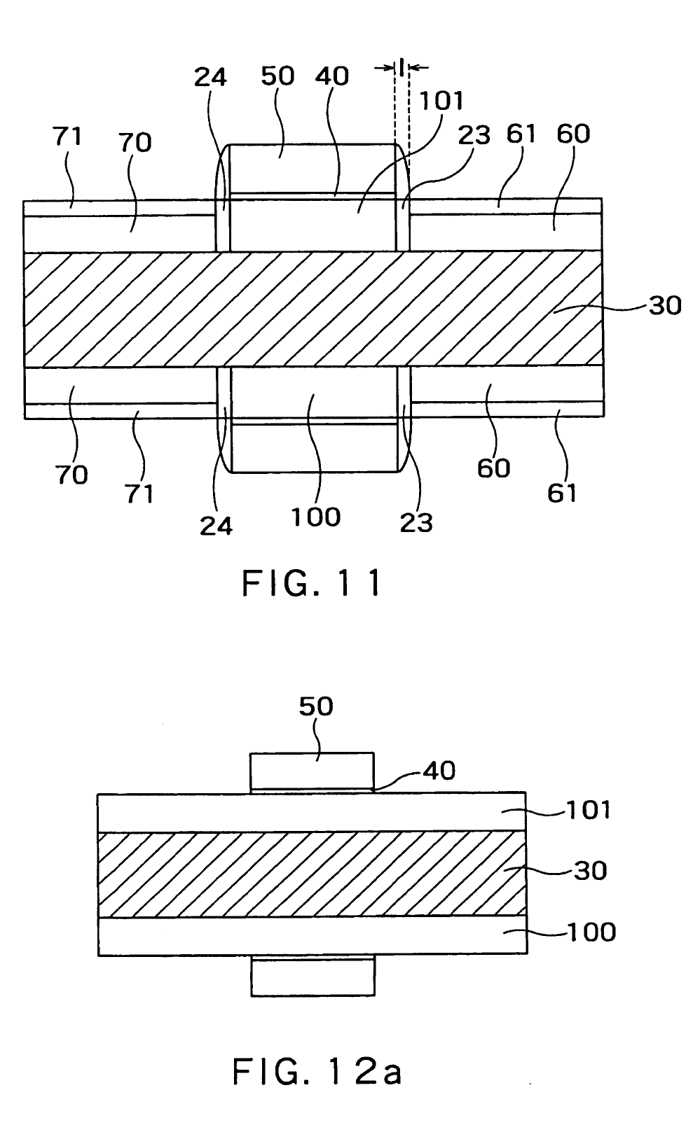

A vertical MOSFET according to a fourth embodiment of the present invention is explained with reference to FIG. 10 to FIGS. 12a to 12d. FIG. 10 is a perspective diagram showing a configuration of the vertical MOSFET according to the fourth embodiment. FIG. 11 is a cross-sectional diagram of the vertical MOSFET cut along a line E1-E2 on the horizontal plane, as seen in the direction of the arrow, shown in FIG. 10. The present embodiment has characteristics in only between the source and the gate and between the drain and the gate, and therefore, can be applied to any of the vertical MOSFETs according to the first to the third embodiments. The application of the characteristics of the present embodiment to the vertical MOSFET according to the third embodiment is explained below as one example. In FIG. 10 to FIGS. 12a to 12d, constituent parts similar to those according to the third embodiment are designated with like reference numerals, and explanation of these parts is omitted.

According to the present embodiment, a source offset 23 is provided between the end of the gate electrode 50 and the end of the source region 60, and a drain offset 24 is provided between the end of the gate electrode 50 and the end of the drain region 70.

As explained above, by providing the source offset 23 and the drain offset 24, an electric field at the end of the source region 60 and at the end of the drain region 70 can be mitigated, thereby suppressing a short channel effect. Based on the standardization of the same off current, a high current driving force can be obtained.

Further effect can be obtained from the source offset 23 and the drain offset 24 when the source and the drain have a metal source configuration and a metal drain configuration, respectively.

Semiconductor layers 100 and 101 on which channels are formed have low impurity concentration of about 2E17 cm-3 or below. Therefore, even when the source offset 23 and the drain offset 24 are provided, the resistance of the channel forming parts near the end of the source region 60 and the end of the drain region 70 can be reduced.

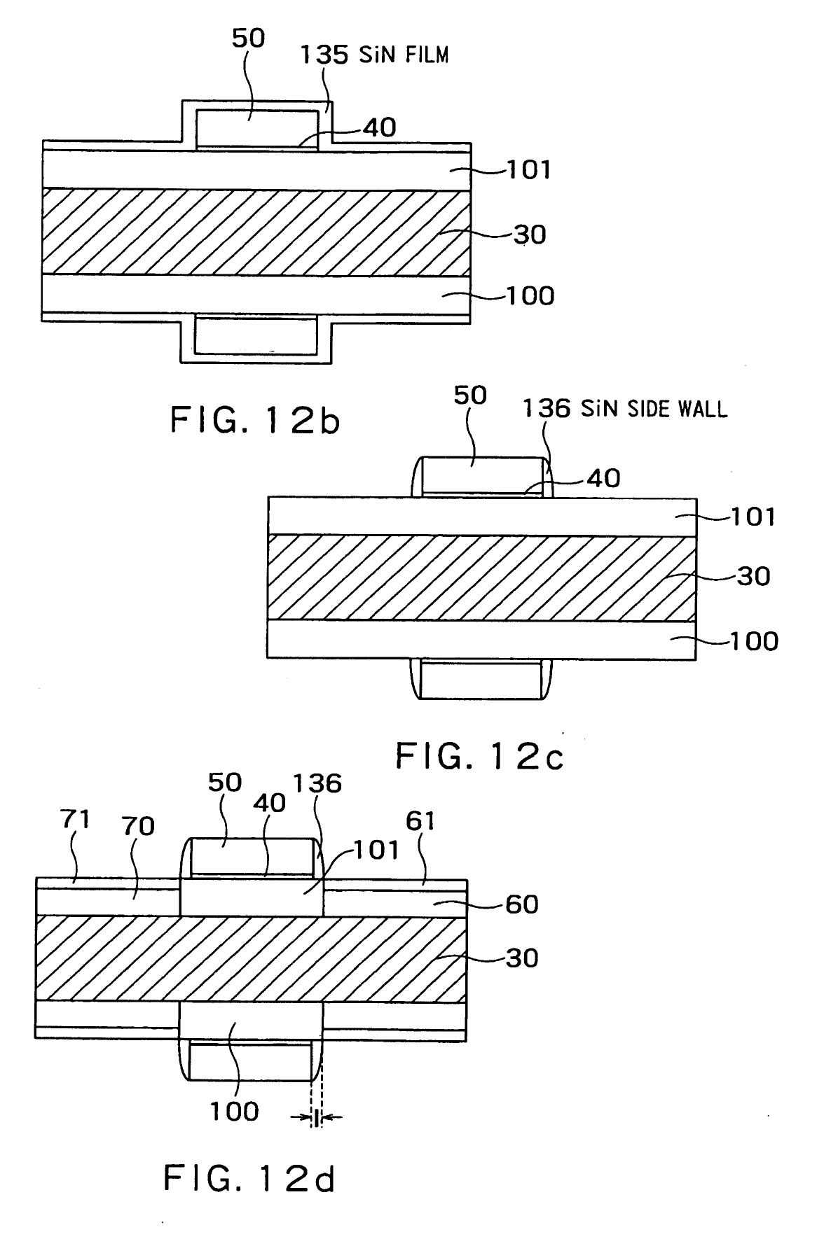

A method of manufacturing the vertical MOSFET having the above configuration is explained below with reference to FIGS. 12a to 12d. FIGS. 12a to 12d are cross-sectional diagrams showing the process of manufacturing the vertical MOSFET. FIGS. 12a to 12d are cross-sectional diagrams of the vertical MOSFET cut along a line E1-E2 on the horizontal plane, as seen in the direction of the arrow, shown in FIG. 10.

The method of manufacturing the vertical MOSFET according to the present embodiment is different from that according to the third embodiment in only the method of forming a source region and a drain region. The manufacturing method up to the step of depositing the gate electrode 50 made of polysilicon is the same as that according to the third embodiment. Therefore, explanation up to this step is omitted.

As shown in FIG. 12a, the gate electrode 50 is formed on the gate insulation film 40. Then, as shown in FIG. 12b, a SiN film 135 is formed on the semiconductor layer 20, the gate insulation film 40, and the gate electrode 50.

Thereafter, as shown in FIG. 12c, the SiN film 135 is etched back to form a SiN side wall 136 on the side walls of the gate insulation film 40 and the gate electrode 50 in self-alignment with the gate electrode 50. When the height of the gate electrode is set two times that of the Fin, SiN can be left on only the side surface of the gate.

Further, as shown in FIG. 12d, the source region 60 and the drain region 70 are formed by injecting boron (B) by the ion injection method into both left and right side surfaces of the first side surface 20a of the semiconductor layer 20 at the outside of the SiN side wall 136 using the gate electrode 50 and the SiN side wall 136 as a mask. As a result, the source offset 23 and the drain offset 24 are formed between the source region 60 and the channel forming region below the gate electrode 50 and between the drain region 70 and the channel forming part below the gate electrode 50, respectively. A width (I) of the source offset 23 and the drain offset 24 is determined based on the width of the SiN side wall 136. The source region 60 and the drain region 70 are formed in self-alignment with the SiN side wall 136.

Thereafter, titanium (Ti) is formed by sputtering on each surface of the source region 60 and the drain region 70. The titanium is heat treated to form the metal silicide films 61 and 71 made of titan silicide in the source region 60 and the drain region 70. As a result, a satisfactory ohmic contact can be obtained between the source region 60 and the metal silicide film 61 and between the drain region 70 and the metal silicide film 71.

In the manner as described above, a vertical MOSFET having the source offset 23 between the edge of the gate electrode 50 and the source region 60, and the drain offset 24 between the edge of the gate electrode 50 and the drain region 70 can be formed.

1. A semiconductor integrated circuit device comprising:
a projected semiconductor layer formed at a part of the upper surface of a semiconductor substrate;
a gate insulation film formed on a first side surface of the semiconductor layer;
a gate electrode formed on the gate insulation film;
a first insulation film formed on a second side surface of the semiconductor layer; and
a source region and a drain region formed within the semiconductor layer to sandwich the gate electrode, wherein the first insulation film has a larger thickness than that of the gate insulation film.

2. The semiconductor integrated circuit device according to claim 1 further comprising:
a second insulation film formed on a upper surface of the semiconductor layer.

3. The semiconductor integrated circuit device according to claim 2, wherein
the second insulation film has a larger thickness than that of the gate insulation film.

4. The semiconductor integrated circuit device according to claim 1 further comprising:
metal silicide layers formed on surfaces of the source region and the drain region.

5. The semiconductor integrated circuit device according to claim 1, wherein
the semiconductor integrated circuit device manufactured on a SOI substrate.

6. A semiconductor integrated circuit device comprising:
a first insulation film formed in a projected manner at a part of the upper surface of a semiconductor substrate;
first and second semiconductor layers formed in a projected manner on the upper surface of the semiconductor substrate such that first side surfaces of the first and the second semiconductor layers are in close contact with opposite side surfaces of the first insulation film, respectively;
a gate insulation film formed on second side surfaces opposite to the first side surfaces of the first and the second semiconductor layers, respectively;
a gate electrode formed on the gate insulation film; and
a source region and a drain region formed on the second side surfaces within the first and the second semiconductor layers, respectively to sandwich the gate electrode.

7. The semiconductor integrated circuit device according to claim 6, wherein
the first insulation film has a larger thickness than that of the gate insulation film.

8. The semiconductor integrated circuit device according to claim 6 further comprising:
a second insulation film formed on the upper surfaces of the first and the second semiconductor layers.

9. The semiconductor integrated circuit device according to claim 6, wherein
the second insulation film has a larger thickness than that of the gate insulation film.

10. The semiconductor integrated circuit device according to claim 6 further comprising:
metal silicide layers formed on surfaces of the source region and the drain region.

11. The semiconductor integrated circuit device according to claim 6, wherein
the semiconductor integrated circuit device manufactured on a SOI substrate.

12. A method of manufacturing a semiconductor integrated circuit device comprising:
forming a trench on a semiconductor substrate;
forming a first insulation film with one end of the first insulation film embedded within the trench, and the other end projected from the surface of the semiconductor substrate;
forming a side wall made of a second insulation film at a side of the projected first insulation film;
etching partially the semiconductor substrate at both sides of the projected first insulation film using the first insulation film and the second insulation film as a mask, thereby forming a projected first semiconductor layer and a projected second semiconductor layer beneath the second insulation film;
forming a gate insulation film on side surfaces of the first and the second semiconductor layers;
forming a gate electrode on the surface of the gate insulation film on the side surface of the first semiconductor layer to the surface of the gate insulation film on the side surface of the second semiconductor layer, by striding on the first insulation film and the second insulation film; and
injecting impurity into the side surfaces of the first and the second semiconductor layers, thereby forming a source region and a drain region to sandwich the gate electrode.

13. The method of manufacturing a semiconductor integrated circuit device according to claim 12, wherein
the first insulation film is formed a larger thickness than that of the gate insulation film.

14. The method of manufacturing a semiconductor integrated circuit device according to claim 12, wherein
the second insulation film is formed a larger thickness than that of the gate insulation film.

15. The method of manufacturing a semiconductor integrated circuit device according to claim 12 further comprising:
forming metal suicide layers on surfaces of the source region and the drain region.

16. A method of manufacturing a semiconductor integrated circuit device comprising:
forming a trench on a semiconductor substrate;
forming a first insulation film with one end of the first insulation film embedded within the trench, and the other end projected from the surface of the semiconductor substrate;
forming a side wall made of a second insulation film at a side of the projected first insulation film;
etching partially the semiconductor substrate at both sides of the projected first insulation film using the first insulation film and the second insulation film as a mask, thereby forming a projected first semiconductor layer and a projected second semiconductor layer beneath the second insulation film;
forming a gate insulation film on side surfaces of the first and the second semiconductor layers;
forming a gate electrode on the surface of the gate insulation film on the side surface of the first semiconductor layer to the surface of the gate insulation film on the side surface of the second semiconductor layer, by striding on the first insulation film and the second insulation film;
forming a side wall on a side part of the semiconductor substrate that is covered with the second insulation film, the gate insulation film, and the gate electrode; and
injecting impurity into a part of the semiconductor substrate that is not covered with the second insulation film, the gate insulation film, the gate electrode, and the side wall, thereby forming a source region and a drain region.

17. The method of manufacturing a semiconductor integrated circuit device according to claim 16, wherein
the first insulation film is formed a larger thickness than that of the gate insulation film.

18. The method of manufacturing a semiconductor integrated circuit device according to claim 16, wherein
the second insulation film is formed a larger thickness than that of the gate insulation film.

19. The method of manufacturing a semiconductor integrated circuit device according to claim 16 further comprising:
forming metal silicide layers on surfaces of the source region and the drain region.
